(19) United States
(12) Patent Application Publication
(10) Pub. No.: US 2016/0268410 A1
(43) Pub. Date: Sep. 15, 2016

(54) SEMICONDUCTOR DEVICE

(71) Applicant: Kabushiki Kaisha Toshiba, Tokyo (JP)

(72) Inventors: Takashi Onizawa, Nomi Ishikawa (JP); Yoshiharu Takada, Nonoichi Ishikawa (JP)

(21) Appl. No.: 14/842,088

(22) Filed: Sep. 1, 2015

(30) Foreign Application Priority Data
Mar. 12, 2015 (JP) 2015-049743

(51) Int. Cl. H01L 29/778; H01L 29/205

(52) U.S. Cl. CPC H01L 29/7787; H01L 29/205

(57) ABSTRACT

A semiconductor device includes: a substrate; a first compound semiconductor layer provided on the substrate; a second compound semiconductor layer provided on the first compound semiconductor layer and having a band gap larger than that of the first compound semiconductor layer; a first element isolation region provided in the first compound semiconductor layer and the second compound semiconductor layer; and a first electrode and a second electrode which are electrically connected to a first conductive region formed from the first and second compound semiconductor layers arranged outside the first element isolation region.

### CROSS-REFERENCE TO RELATED APPLICATIONS

This application is based upon and claims the benefit of priority from Japanese Patent Application No. 2015-049743, filed Mar. 12, 2015, the entire contents of which are incorporated herein by reference.

### FIELD

Embodiments described herein relate generally to a semiconductor device and, more particularly, to a semiconductor device including a compound semiconductor.

### BACKGROUND

A semiconductor element using a nitride semiconductor is used in a power device or high-frequency device. A light-emitting diode (LED) that is a semiconductor light-emitting element using a nitride semiconductor is used in a display device, illumination, or the like. An element using a compound semiconductor such as a nitride semiconductor has excellent material characteristics and can therefore implement a high-performance semiconductor element.

Forming such a nitride semiconductor element on a silicon (Si) substrate is advantageous for mass production. However, the difference of the lattice constant or the coefficient of thermal expansion readily produces a defect, crack, and the like. The crack causes a failure in a power device or the like, resulting in a low yield.

### BRIEF DESCRIPTION OF THE DRAWINGS

FIG. 1 is a plan view of a semiconductor device according to the first embodiment;

FIG. 2 is a sectional view of the semiconductor device taken along a line II-II in FIG. 1;

FIG. 3 is a sectional view of the semiconductor device taken along a line III-III in FIG. 1;

FIG. 4 is a plan view of a semiconductor device 1 with a crack 50;

FIG. 5 is a sectional view of the semiconductor device taken along a line V-V in FIG. 4;

FIG. 6 is a plan view of a semiconductor device according to the second embodiment;

FIG. 7 is a sectional view of the semiconductor device taken along a line VII-VII in FIG. 6;

FIG. 8 is a plan view of a semiconductor device according to the third embodiment;

FIG. 9 is a plan view of a partial region of the semiconductor device shown in FIG. 8;

FIG. 10 is a plan view of a semiconductor device according to the fourth embodiment;

FIG. 11 is a sectional view of the semiconductor device taken along a line XI-XI in FIG. 10; and

FIG. 12 is a plan view of a semiconductor device according to the fifth embodiment.

### DETAILED DESCRIPTION

In general, according to one embodiment, there is provided a semiconductor device comprising:

a substrate;

a first compound semiconductor layer provided on the substrate;

a second compound semiconductor layer provided on the first compound semiconductor layer and having a band gap larger than that of the first compound semiconductor layer;

a first element isolation region provided in the first compound semiconductor layer and the second compound semiconductor layer; and

a first electrode and a second electrode which are electrically connected to a first conductive region formed from the first and second compound semiconductor layers arranged outside the first element isolation region.

Embodiments will now be described with reference to the accompanying drawings. The drawings are merely schematic or conceptual, and the dimensions and ratios in these drawings do not necessarily match the actuality. Several embodiments to be described below merely exemplify devices and methods for embodying the technical concepts of the present invention, and the shapes, structures, layouts, and the like of the components do not limit the technical concepts of the present invention. Note that in the following explanation, the same reference numerals denote elements having the same functions and arrangements, and a repetitive explanation will be made only when necessary.

### First Embodiment

### [1] Arrangement of Semiconductor Device

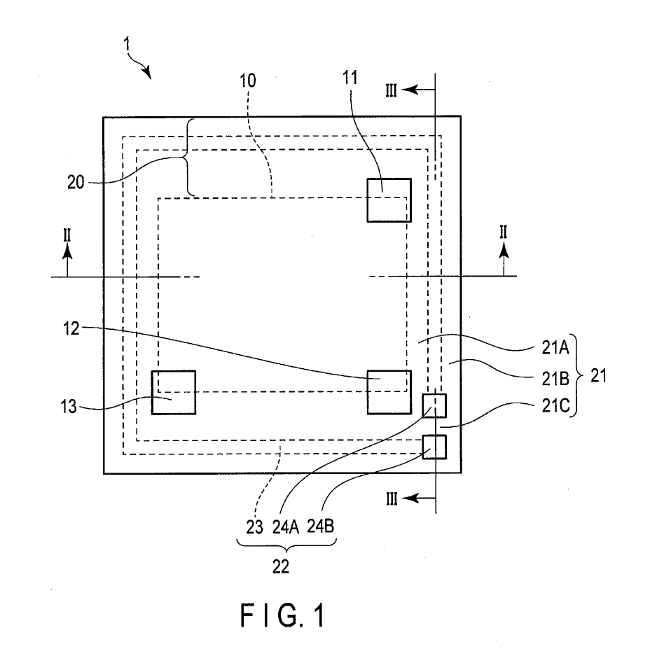

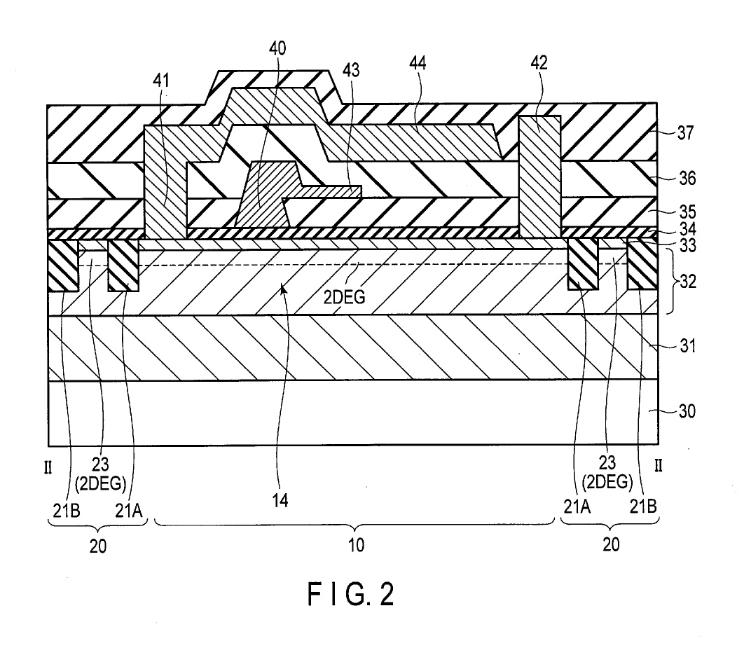

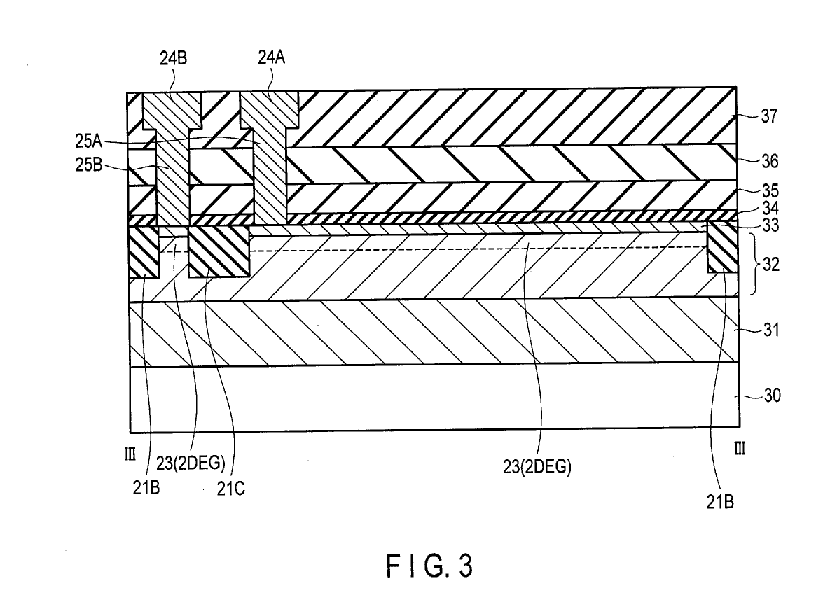

FIG. 1 is a plan view of a semiconductor device 1 according to the first embodiment. FIG. 2 is a sectional view of the semiconductor device 1 taken along a line II-II in FIG. 1. FIG. 3 is a sectional view of the semiconductor device 1 taken along a line III-III in FIG. 1. The semiconductor device 1 includes an element region 10 and a peripheral region 20.

A semiconductor element 14 is provided in the element region 10. The semiconductor element 14 is formed from a power device and/or a high-frequency device using a compound semiconductor. More specifically, the semiconductor element 14 is formed from an HFET (Hetero-junction Field Effect Transistor) or an HEMT (High Electron Mobility Transistor).

The peripheral region 20 is provided around the element region 10 and is electrically insulated from the element region 10. The peripheral region 20 has a function of electrically insulating the side surfaces of the semiconductor device 1 from the element region 10. An insulating element isolation region 21 and a crack determination element 22 are provided in the peripheral region 20. The crack determination element 22 is used to determine whether a crack is formed in the semiconductor device 1 (particularly in a compound semiconductor layer included in the semiconductor device 1).

The arrangement of each of the element region 10 and the peripheral region 20 will be described below in detail.

### [1-1] Element Region 10

As shown in FIGS. 2 and 3, the semiconductor device 1 includes a buffer layer 31, a channel layer 32, a barrier layer 33, and various electrodes sequentially stacked on a substrate 30.

The substrate 30 is formed from a silicon (Si) substrate having, for example, the (111) plane as the principal surface. As the substrate 30, sapphire (Al₂O₃), silicon carbide (SiC), gallium phosphide (GaP), indium phosphide (InP), gallium arsenide (GaAs), or the like may be used. As the substrate 30, a substrate including an insulating layer can also be used. For example, an SOI (Silicon On Insulator) substrate can be used as the substrate 30. The substrate 30 is not limited to those described above, and any other substrate is usable as long as it is a single-crystal substrate capable of growing an epitaxial layer.

The buffer layer 31 has a function of relaxing distortion caused by the difference between the lattice constant of the substrate 30 and the lattice constant of a nitride semiconductor layer formed on the buffer layer 31 and also controlling the crystallinity of the nitride semiconductor layer formed on the buffer layer 31. The buffer layer 31 also has a function of suppressing a chemical reaction between an element (for example, silicon (Si)) of the substrate 30 and an element (for example, gallium (Ga)) contained in the nitride semiconductor layer formed on the buffer layer 31. The buffer layer 31 is made of, for example, AlₓGa₁₋ₓN (0≦x≦1). In this embodiment, the buffer layer 31 is made of AlN. Note that the buffer layer 31 is not an element indispensable for the embodiment and may be omitted.

The channel layer 32 is a layer in which the channel (current path) of the transistor is formed. The channel layer 32 is made of InₓAl_{y}Ga_{(1-x-y)}N (0≦x<1, 0≦y<1, 0≦x+y<1). The channel layer 32 is an undoped layer and is made of a nitride semiconductor of good crystallinity (high quality). “Undoped” means that no impurity is doped intentionally, and allows, for example, an impurity amount incorporated in the manufacturing process or the like. In this embodiment, the channel layer 32 is made of undoped GaN.

The barrier layer 33 forms a hetero junction together with the channel layer 32. The barrier layer 33 is formed from a nitride semiconductor layer having a band gap larger than that of the channel layer 32. The barrier layer 33 is made of InₓAl_{y}Ga_{(1-x-y)}N (0≦x<1, 0≦y<1, 0≦x+y<1). In this embodiment, the barrier layer 33 is made of, for example, undoped aluminum gallium nitride (AlGaN).

Note that the plurality of semiconductor layers included in the semiconductor device 1 are sequentially formed by epitaxial growth using, for example, MOCVD (Metal Organic Chemical Vapor Deposition). That is, the plurality of semiconductor layers included in the semiconductor device 1 are formed from epitaxial layers.

A source electrode 41 and a drain electrode 42 are provided on the barrier layer 33 while being spaced apart from each other. The source electrode 41 and the barrier layer 33 (more specifically, 2DEG)—are in ohmic contact. Similarly, the drain electrode 42 and the barrier layer 33 (more specifically, 2DEG) are in ohmic contact. That is, each of the source electrode 41 and the drain electrode 42 is formed so as to contain a material that comes into ohmic contact with (joins) the barrier layer 33. As the source electrode 41 and the drain electrode 42, for example, titanium (Ti), tantalum (Ta), aluminum (Al), nickel (Ni), platinum (Pt), a nitride thereof, or a stacked structure thereof is used.

A gate insulating film 34 is provided on the barrier layer 33. As the gate insulating film 34, silicon oxide (SiO₂), silicon nitride (SiN), silicon oxynitride (SiON), aluminum oxide (Al₂O₃), aluminum nitride (AlN), or the like is used. A gate electrode 40 is provided on the gate insulating film 34 between the source electrode 41 and the drain electrode 42. As the gate electrode 40, titanium (Ti), tantalum (Ta), aluminum (Al), nickel (Ni), platinum (Pt), a nitride thereof, a stacked structure thereof, or the like is used. To increase the breakdown voltage between the gate and the drain, the distance between the gate electrode 40 and the drain electrode 42 is set to be longer than that between the gate electrode 40 and the source electrode 41.

The semiconductor element 14 is formed from the source electrode 41, the drain electrode 42, the gate electrode 40, the gate insulating film 34, and part of the nitride semiconductor layers. The semiconductor element 14 shown in FIGS. 2 and 3 is a MIS (Metal Insulator Semiconductor) HFET. Note that the semiconductor element 14 is not limited to the MIS HFET, and may be a Schottky barrier HFET in which the gate electrode 40 and the barrier layer 33 form a Schottky barrier without forming the gate insulating film 34. A junction gate structure may be applied to an HFET. The junction gate structure is formed by providing a p-type nitride semiconductor layer (for example, GaN layer) on the barrier layer 33 and providing the gate electrode 40 on the p-type nitride semiconductor layer. FIG. 2 illustrates a single HEMT as an example for the sake of simplicity. However, a plurality of lines of transistor structures (in general, repetition of source/gate/drain/gate/source/gate . . . ) may be formed. Alternatively, several types of transistors may be formed in one chip.

In the hetero junction structure between the channel layer 32 and the barrier layer 33, distortion occurs in the barrier layer 33 because the lattice constant of the barrier layer 33 is smaller than that of the channel layer 32. A piezoelectric effect produced by the distortion causes piezoelectric polarization in the barrier layer 33, and 2DEG (Two-Dimensional electron Gas) is generated in the interface between the channel layer 32 and the barrier layer 33. The 2DEG serves as the channel between the source electrode 41 and the drain electrode 42. An electric field applied to the channel layer 32 is controlled based on a gate voltage applied to the gate electrode 40, enabling control of the drain current. Since the mobility of a carrier flowing in the 2DEG is high, the semiconductor element 14 can perform a very fast switching operation.

As shown in FIG. 1, the semiconductor device 1 includes a gate electrode pad 11, a source electrode pad 12, and a drain electrode pad 13. The gate electrode pad 11 is electrically connected to the gate electrode 40. The source electrode pad 12 is electrically connected to the source electrode 41. The drain electrode 42 is electrically connected to the drain electrode pad 13. The electrode pads 11, 12, and 13 are exposed to the upper surface of the semiconductor device 1 and used to electrically connect the semiconductor device 1 to an external device (external circuit).

### (Arrangement of Field Plate Electrode)

The semiconductor device 1 includes a field plate electrode (gate field plate electrode) electrically connected to the gate electrode 40, and a field plate electrode (source field plate electrode) electrically connected to the source electrode 41. That is, the semiconductor device 1 has a so-called double field plate structure.

An interlayer dielectric layer 35 is provided on the gate electrode 40 and the gate insulating film 34. As the interlayer dielectric layer 35, silicon oxide (SiO₂), silicon nitride (SiN), a high-k material, or the like is used. Examples of the high-k material are hafnium oxide (HfO₂), aluminum oxide (Al₂O₃), and aluminum nitride (AlN).

A gate field plate electrode 43 is provided on the interlayer dielectric layer 35. The gate field plate electrode 43 is electrically connected to the gate electrode 40. The gate field plate electrode 43 projects from above the gate electrode 40 toward the drain electrode 42. The end of the gate field plate electrode 43 is arranged closer to the side of the drain electrode 42 than the end of the gate electrode 40.

An interlayer dielectric layer 36 is provided on the gate field plate electrode 43 and the interlayer dielectric layer 35. As the interlayer dielectric layer 36, silicon oxide (SiO₂), silicon nitride (SiN), a high-k material, or the like is used, as in the interlayer dielectric layer 35.

A source field plate electrode 44 is provided on the interlayer dielectric layer 36. The source field plate electrode 44 is electrically connected to the source electrode 41. The source field plate electrode 44 projects from above the source electrode 41 toward the drain electrode 42. The end of the source field plate electrode 44 is arranged closer to the side of the drain electrode 42 than the end of the gate field plate electrode 43.

An interlayer dielectric layer (protective layer) 37 is provided on the interlayer dielectric layer 36 and the source field plate electrode 44. The protective layer 37 is also called a passivation layer. The protective layer 37 is made of an insulator, and silicon nitride (SiN), silicon oxide (SiO₂), or the like is used.

Note that the field plate electrodes are not elements indispensable for the embodiment. Hence, the semiconductor device 1 need not always include the field plate electrodes. The semiconductor device 1 may include only one of the gate field plate electrode and the source field plate electrode.

### [1-2] Peripheral Region 20

The arrangement of the peripheral region 20 will be described next. As described above, the element isolation region 21 and the crack determination element 22 are provided in the peripheral region 20. The crack determination element 22 includes a conductive region 23, electrode pads 24A and 24B, and contact plugs 25A and 25B.

The conductive region 23 is provided to surround the element region 10. The conductive region 23 is not a perfect rectangle, and is partially cut. The conductive region 23 has the same arrangement as the hetero junction provided in the element region 10, and also has 2DEG. That is, in this embodiment, the crack determination element 22 is formed using the conductive region 23 having the same arrangement as the 2DEG in the element region 10.

The element isolation region 21 is provided in the channel layer 32 and the barrier layer 33 in the peripheral region 20. The element isolation region 21 has insulating properties (is made of an insulator). The element isolation region 21 includes element isolation regions 21A, 21B, and 21C. The element isolation region 21 is formed by, for example, performing insulating treatment of implanting impurity ions into the nitride semiconductor layers (the barrier layer 33 and the channel layer 32) and breaking the crystals in the nitride semiconductor layers. As the impurity for the insulating treatment, argon (Ar), boron (B), iron (Fe), or the like is used. Hence, 2DEG is not generated in the element isolation region 21.

The element isolation region 21A is arranged between the conductive region 23 and the element region 10, and electrically insulates them from each other. In other words, the conductive region 23 is arranged outside the element isolation region 21A. Based on the element isolation region 21A, “outside” is the end (side surface) side of the substrate 30 with respect to the element isolation region 21A. The element isolation region 21B is arranged outside the conductive region 23, and electrically insulates the side surfaces of the semiconductor device 1 from the conductive region 23. The element isolation region 21C cuts part of the conductive region 23.

The contact plugs 25A and 25B are provided at the two ends of the conductive region 23 (the portion cut by the element isolation region 21C), respectively. The contact plugs 25A and 25B are in ohmic contact with the barrier layer 33 (more specifically, 2DEG) that forms the conductive region 23. That is, the contact plugs 25A and 25B are formed so as to contain a material that comes into ohmic contact with (joins) the barrier layer 33. As the contact plugs 25A and 25B, titanium (Ti), gold (Au), platinum (Pt), nickel (Ni), aluminum (Al), copper (Cu), a nitride thereof, an alloy containing at least one of them, or the like is used.

The electrode pads 24A and 24B are provided on the contact plugs 25A and 25B, respectively. The electrode pads 24A and 24B are exposed to the upper surface of the semiconductor device 1. As the electrode pads 24A and 24B, gold (Au), platinum (Pt), nickel (Ni), aluminum (Al), copper (Cu), a nitride thereof, an alloy containing at least one of them, or the like is used.

### [2] Crack Determination Operation

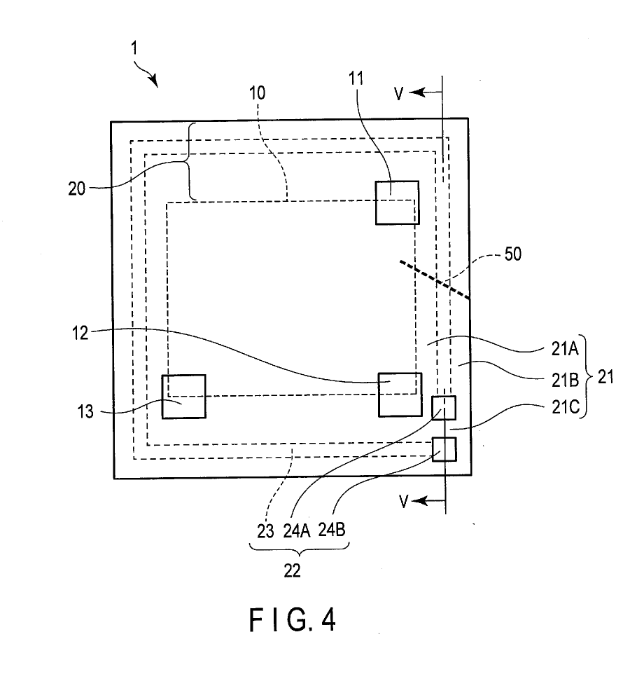

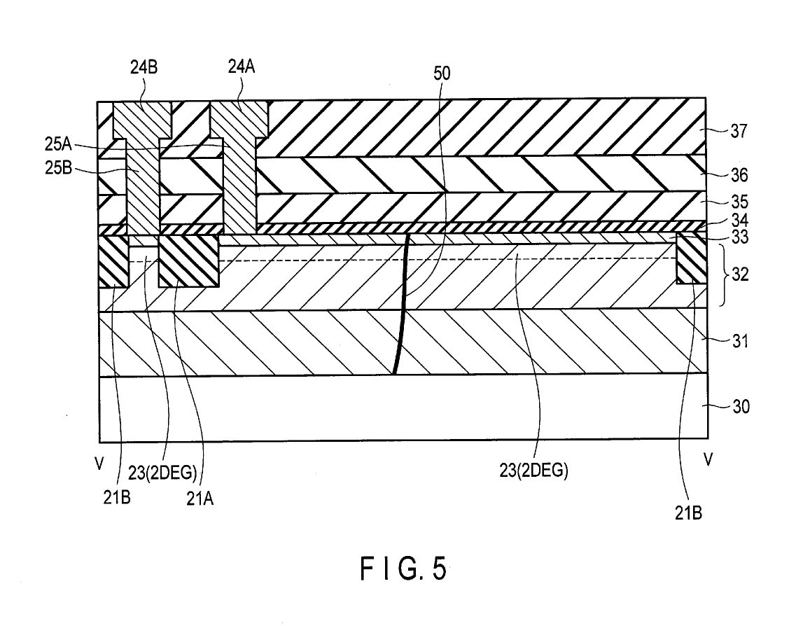

A crack determination operation using the crack determination element 22 will be described next. FIG. 4 is a plan view of the semiconductor device 1 with a crack 50. FIG. 5 is a sectional view of the semiconductor device 1 taken along a line V-V in FIG. 4.

As shown in FIGS. 4 and 5, the crack 50 is formed from a side surface of the semiconductor device 1 to the element region 10, and is formed across the buffer layer 31, the channel layer 32, and the barrier layer 33. The crack 50 cuts part of the conductive region 23 that forms the crack determination element 22.

For example, in a test process before product shipment, it is determined whether a crack is produced in the semiconductor device 1. That is, in the test process, the conduction state between the electrode pads 24A and 24B that constitute the crack determination element 22 is inspected using, for example, a tester. If the conductive region 23 is cut by the crack 50, the resistance value between the electrode pads 24A and 24B is higher than in a case where the semiconductor device 1 has no crack. In this way, it can be determined using the crack determination element 22 whether a crack is produced in the semiconductor device 1, particularly, in the nitride semiconductor layers.

### [3] Effects of First Embodiment

The semiconductor device 1 according to the first embodiment includes the crack determination element 22 using a two-dimensional electron gas (2DEG) in the peripheral region 20. The crack determination element 22 includes the conductive region 23 that is electrically insulated from the element region 10 by the element isolation region 21A and surrounds the element region 10, and the electrode pads 24A and 24B electrically connected to the two ends of the conductive region 23. The conductive region 23 has the same arrangement as the hetero junction provided in the element region 10, and has a conductivity.

Hence, according to the first embodiment, the resistance value between the electrode pads 24A and 24B is measured using a tester or the like, thereby determining whether a crack is produced in the semiconductor device 1. This makes it possible to easily determine whether the semiconductor device 1 is a defective chip.

In addition, the presence/absence of a crack can be determined by electrical characteristic evaluation using a tester or the like. It is therefore possible to improve the inspection accuracy and reduce the inspection time and inspection cost as compared to a case where visual inspection is performed.

Furthermore, after shipment of the semiconductor device 1, the crack determination element 22 can be used as a guard ring. For example, the conductive region 23 of the crack determination element 22 is set to the same voltage (ground voltage=0 V) as the source electrode pad 12. For example, the electrode pads 24A and 24B and the source electrode pad 12 are electrically connected using wiring. Since this can relax an external field applied to the semiconductor element 14, the operation characteristic of the semiconductor element 14 can be improved.

### Second Embodiment

In the second embodiment, a guard ring using 2DEG is provided in a peripheral region 20 in addition to a crack determination element 22.

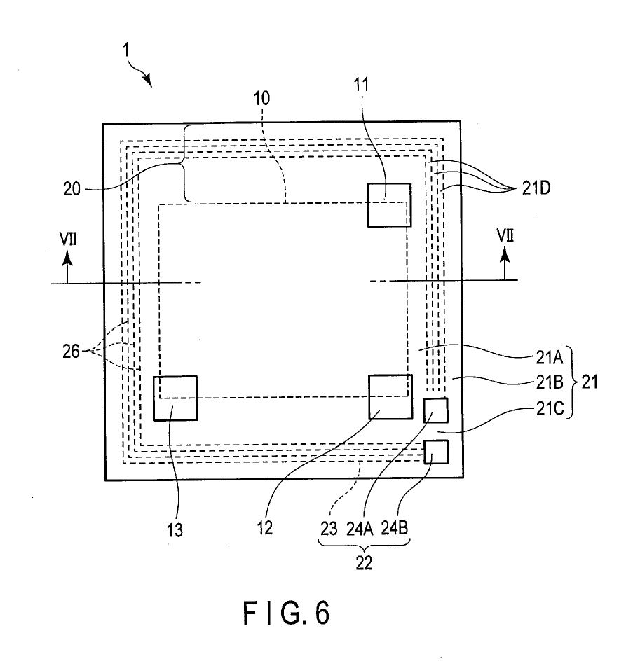

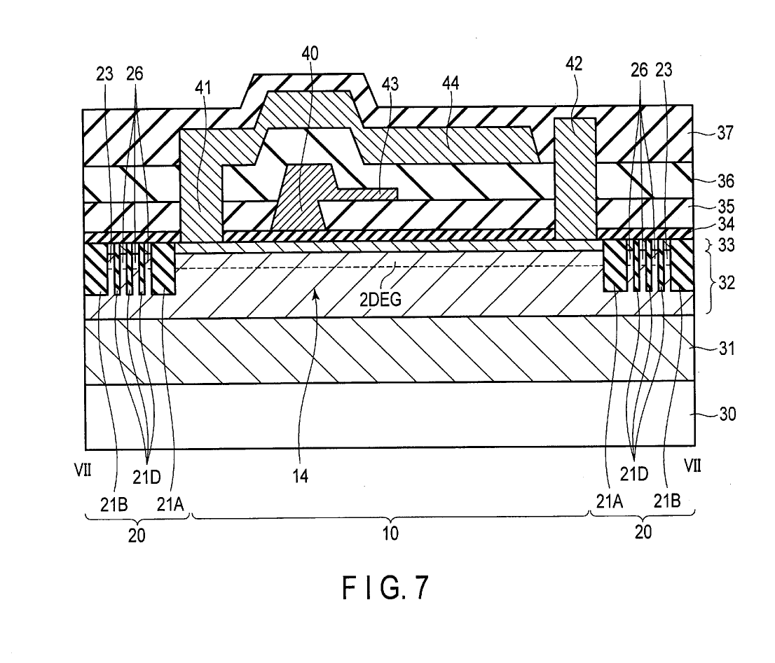

FIG. 6 is a plan view of a semiconductor device 1 according to the second embodiment. FIG. 7 is a sectional view of the semiconductor device 1 taken along a line VII-VII in FIG. 6. As in the first embodiment, the crack determination element 22 (including a conductive region 23, electrode pads 24A and 24B, and contact plugs 25A and 25B) is provided in the peripheral region 20.

One or a plurality of guard rings 26 are provided in the peripheral region 20. FIG. 6 shows three guard rings 26 as an example. Note that although the conductive region 23 and the guard rings 26 are indicated by lines in FIG. 6 to avoid complication of the drawing, each of them has a predetermined width. The guard rings 26 are provided to surround an element region 10. The guard rings 26 have the same arrangement as the hetero junction provided in the element region 10, and also have a conductivity. The guard rings 26 are partially cut, and their one-end sides are electrically connected to the electrode pad 24B via the contact plug 25B. The other-end sides of the guard rings 26 are not electrically connected to the electrode pad 24A.

The conductive region 23 is electrically connected to the electrode pads 24A and 24B, as in the first embodiment. The guard rings 26 and the conductive region 23 are electrically insulated by a plurality of element isolation regions 21D. Note that in FIG. 6, the conductive region 23 is arranged outside the guard rings 26. However, their positions may be exchanged.

The guard rings 26 are set to the same voltage (ground voltage=0 V) as a source electrode pad 12. For example, the electrode pad 24B and the source electrode pad 12 are electrically connected using wiring. Since this can relax an external field applied to a semiconductor element 14, the operation characteristic of the semiconductor element 14 can be improved.

### Third Embodiment

In the third embodiment, the two ends of a conductive region 23 that constitutes a crack determination element 22 are configured to extend from outside a peripheral region 20 to inside. This improves crack determination accuracy and enables to determine a crack formed in a region between electrode pads 24A and 24B.

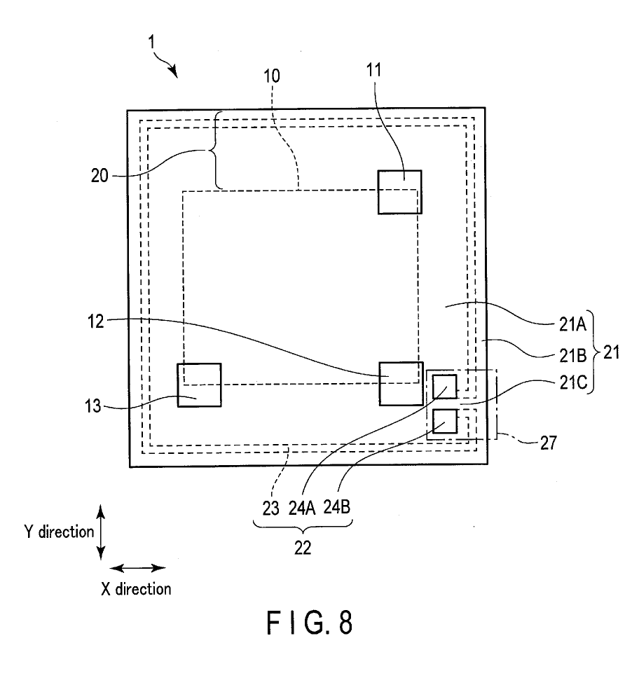

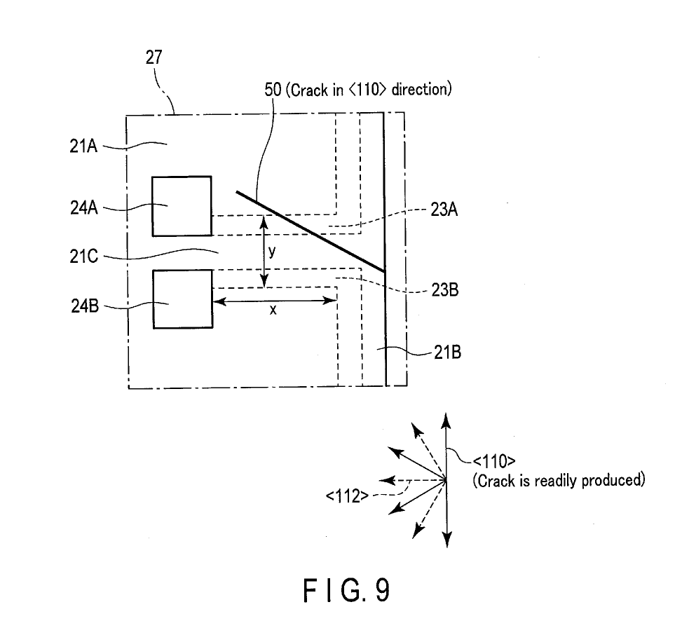

FIG. 8 is a plan view of a semiconductor device 1 according to the third embodiment. FIG. 9 is a plan view of a partial region 27 of the semiconductor device 1 shown in FIG. 8.

The conductive region 23 includes conductive regions 23A and 23B extending from the two ends of the cut portion in the X direction (from outside the peripheral region 20 to inside). One end of the conductive region 23A is electrically connected to the electrode pad 24A via a contact plug 25A, and one end of the conductive region 23B is electrically connected to the electrode pad 24B via a contact plug 25B.

Nitride semiconductor layers (including a buffer layer 31 a channel layer 32, and a barrier layer 33) are epitaxially grown on a silicon (Si) substrate 30 having, for example, the (111) plane as the principal surface. In this case, a crack 50 is readily formed in the <110> direction of the substrate 30. In this embodiment, the conductive regions 23A and 23B extend in the <112> direction of the substrate 30.

Additionally, in this embodiment, letting x be the X-direction length of the conductive regions 23A and 23B, and y be the Y-direction length between the edges of the conductive regions 23A and 23B on the sides far apart from each other, x is set to 1.74 times (=√3 times) or more of y. This can improve the determination accuracy of a crack produced in the region between the electrode pads 24A and 24B.

### Fourth Embodiment

In the fourth embodiment, a guard ring 60 is provided in a peripheral region 20 using a wiring layer.

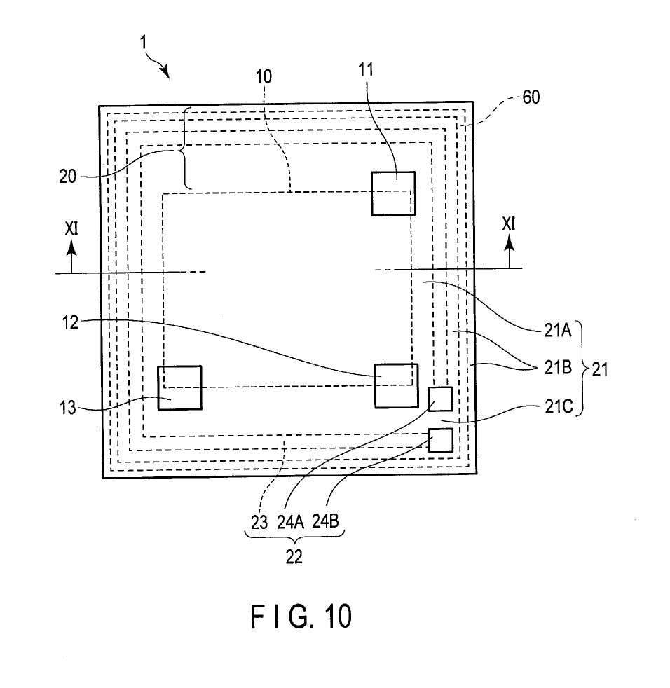

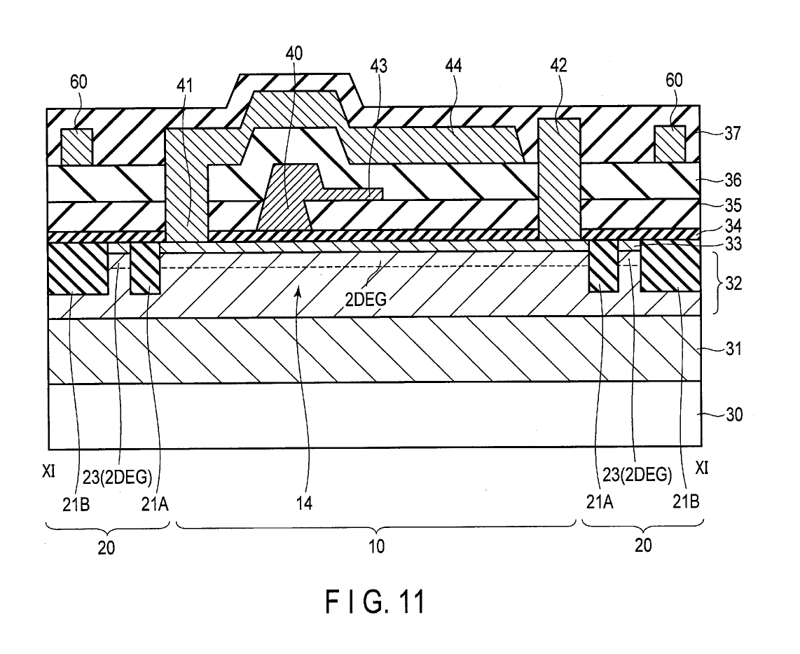

FIG. 10 is a plan view of a semiconductor device 1 according to the fourth embodiment. FIG. 11 is a sectional view of the semiconductor device 1 taken along a line XI-XI in FIG. 10.

The guard ring 60 formed from a wiring layer is provided in the peripheral region 20. The guard ring 60 is arranged outside a conductive region 23 when viewed from the upper side. The guard ring 60 is formed from, for example, a wiring layer of the same level as a source field plate electrode 44. In the arrangement example of FIG. 10, the guard ring 60 is provided in a protective layer 37. The guard ring 60 is made of a conductive material, for example, a metal such as copper (Cu), gold (Au), or aluminum (Al).

The guard ring 60 is set to the same voltage (ground voltage=0 V) as a source electrode pad 12. For example, the guard ring 60 and the source electrode pad 12 are electrically connected using wiring. Since this can relax an external field applied to a semiconductor element 14, the operation characteristic of the semiconductor element 14 can be improved.

### Fifth Embodiment

In the fifth embodiment, a conductive region that constitutes a crack determination element 22 is divided into a plurality of parts, thereby reducing the resistance value of each conductive region.

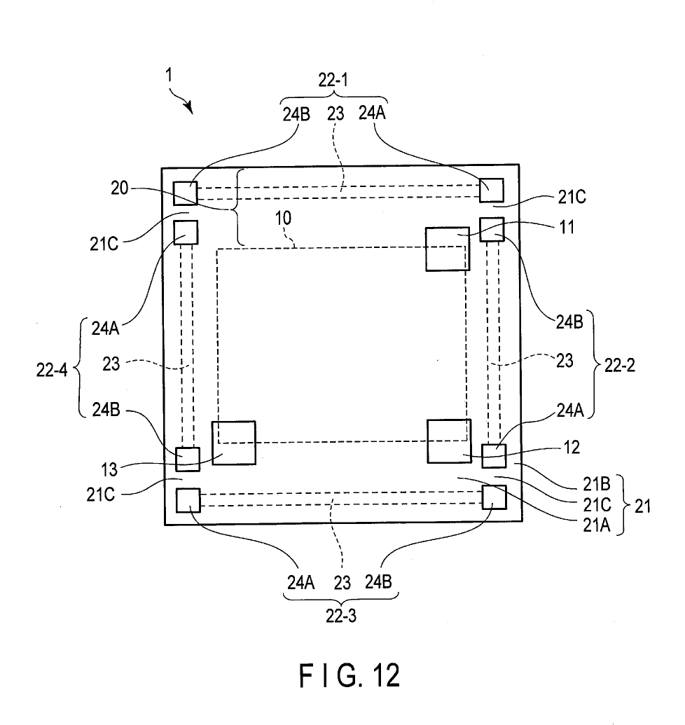

FIG. 12 is a plan view of a semiconductor device 1 according to the fifth embodiment. The semiconductor device 1 includes a plurality of crack determination elements 22. In the example of FIG. 12, the crack determination element 22 is divided into four parts, and includes crack determination elements 22-1 to 22-4.

Each of the crack determination elements 22-1 to 22-4 includes a conductive region 23, electrode pads 24A and 24B, and contact plugs 25A and 25B. Element isolation regions 21C are provided between the adjacent crack determination elements 22.

Due to factors such as an increase in the resistance value caused by thinning of the conductive region provided in the crack determination element, and/or an increase in the resistance value caused by 2DEG, the resistance value of the crack determination element may increase, and measurement of the resistance value may become difficult. To avoid this, in the fifth embodiment, the length of the conductive region 23 provided in each of the crack determination elements 22-1 to 22-4 is shortened as compared to the first embodiment. This can reduce the resistance value of the conductive region 23 formed from 2DEG. As a result, a resistance value difference generated by the presence/absence of a crack becomes large in each crack determination element 22. It is therefore possible to improve the accuracy of determining the presence/absence of a crack.

Note that in this embodiment, an HFET or HEMT has been described as an example of the semiconductor element provided in the element region. However, the present embodiment is not limited to this and may be applied to another semiconductor device using 2DEG generated in the hetero junction interface.

In this embodiment, the semiconductor device is formed using a nitride semiconductor. However, the present embodiment is not limited to this, and the semiconductor device may be formed using a compound semiconductor other than the nitride semiconductor.

In this specification, “nitride semiconductor” includes semiconductors of all compositions obtained by changing composition ratios x and y within their ranges in a chemical formula InₓAl_{y}Ga_{(1-x-y)}N (0≦x≦1, 0≦y≦1, 0≦x+y≦1). “Nitride semiconductor” also includes semiconductors further containing a group V element other than N (nitrogen) semiconductors further containing various elements added to control various kinds of physical properties such as a conductivity type, and semiconductors further containing various elements unintentionally incorporated in the above chemical formula.

In the specification of the present application, “stack” includes a case where layers are stacked with another layer inserted between them as well as a case where layers are stacked in contact with each other. In addition, “provided on” includes a case where layers are provided with another layer inserted between them as well as a case where layers are provided in direct contact with each other.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a substrate;
a first compound semiconductor layer provided on the substrate;
a second compound semiconductor layer provided on the first compound semiconductor layer and having a band gap larger than that of the first compound semiconductor layer;
a first element isolation region provided in the first compound semiconductor layer and the second compound semiconductor layer; and
a first electrode and a second electrode which are electrically connected to a first conductive region formed from the first and second compound semiconductor layers arranged outside the first element isolation region.

2. The device of claim 1, wherein the first element isolation region is arranged to surround an element region in which a semiconductor element is provided.

3. The device of claim 1, further comprising a second element isolation region provided in the first compound semiconductor layer and the second compound semiconductor layer and outside the first conductive region.

4. The device of claim 1, further comprising a second conductive region formed from the first and second compound semiconductor layers arranged between the first element isolation region and the first conductive region, the second conductive region being electrically connected to the first electrode.

5. The device of claim 4, wherein the second conductive region is arranged to surround an element region in which a semiconductor element is provided.

6. The device of claim 4, further comprising a third element isolation region provided in the first compound semiconductor layer and the second compound semiconductor layer and between the first conductive region and the second conductive region.

7. The device of claim 1, wherein the first conductive region comprises a first portion extending along an edge of the substrate, and a second portion extending from one end of the first portion to inside of the substrate, and
one end of the second portion is electrically connected to the first electrode.

8. The device of claim 1, further comprising:
an interlayer dielectric layer provided on the second compound semiconductor layer; and
a conductive layer provided in the interlayer dielectric layer and arranged to surround an element region in which a semiconductor element is provided.

9. The device of claim 8, wherein the conductive layer is made of a metal.

10. The device of claim 1, further comprising a third electrode and a fourth electrode which are electrically connected to a third conductive region formed from the first and second compound semiconductor layers arranged outside the first element isolation region.

11. The device of claim 10, wherein the first conductive region is arranged along a first side surface of the substrate, and
the third conductive region is arranged along a second side surface of the substrate.

12. The device of claim 1, wherein each of the first and second compound semiconductor layers comprises a nitride semiconductor layer.

13. The device of claim 1, wherein each of the first and second compound semiconductor layers includes GaN.

14. The device of claim 1, further comprising a semiconductor element provided in an element region,
the semiconductor element comprising an HFET (Hetero-junction Field Effect Transistor).

15. A semiconductor device comprising:
a substrate;
a first compound semiconductor layer provided on the substrate and including GaN;
a second compound semiconductor layer provided on the first compound semiconductor layer and including AlGaN;
a first element isolation region provided in the first compound semiconductor layer and the second compound semiconductor layer; and
a first electrode and a second electrode which are electrically connected to a first conductive region formed from the first and second compound semiconductor layers arranged outside the first element isolation region.

16. The device of claim 15, wherein the first element isolation region is arranged to surround an element region in which a semiconductor element is provided.

17. The device of claim 15, further comprising a second element isolation region provided in the first compound semiconductor layer and the second compound semiconductor layer and outside the first conductive region.

18. The device of claim 15, further comprising a second conductive region formed from the first and second compound semiconductor layers arranged between the first element isolation region and the first conductive region, the second conductive region being electrically connected to the first electrode.

19. The device of claim 18, wherein the second conductive region is arranged to surround an element region in which a semiconductor element is provided.

20. The device of claim 18, further comprising a third element isolation region provided in the first compound semiconductor layer and the second compound semiconductor layer and between the first conductive region and the second conductive region.
